(19) United States
(12) Patent Application Publication
(10) Pub. No.: US 2026/0268193 A1
(43) Pub. Date: Sep. 10, 2026

(54) DOUBLE TRANSMON COUPLERS FOR MEDIATING INTERACTIONS BETWEEN QUANTUM BITS

(71) Applicant: International Business Machines Corporation, Armonk, NY (US)

(72) Inventor: Aaron Finck, White Plains, NY (US)

(21) Appl. No.: 18/990,353

(22) Filed: Dec. 20, 2024

(51) Int. Cl. G06N 10/40; H10N 60/12

(52) U.S. Cl. CPC G06N 10/40; H10N 60/12

(57) ABSTRACT

A device comprises a superconducting integrated circuit which comprises a tunable coupler. The tunable coupler comprises a first node, a second mode, a first transmon, a second transmon, and a flux-tunable inductive coupler. The first node is coupled to a first quantum bit, and the second node is coupled to a second quantum bit. The first transmon comprises a first Josephson junction, and the second transmon comprises a second Josephson junction. The flux-tunable inductive coupler comprises a superconducting loop that couples the first transmon and the second transmon. The superconducting loop comprises a third Josephson junction. The first Josephson junction, the second Josephson junction, and the third Josephson junction are coupled in series between the first node and the second node of the tunable coupler.

### BACKGROUND

This disclosure relates generally to superconducting quantum computing systems and, in particular, techniques for mediating interactions between quantum bits using flux-tunable couplers. A quantum computing system can be implemented using superconducting circuit quantum electrodynamics (cQED) architectures that are constructed using quantum circuit components such as, e.g., superconducting quantum bits and other types of superconducting quantum devices that are controlled using microwave and/or flux-bias control signals. In general, superconducting quantum bits (qubits) are electronic circuits which are implemented using components such as superconducting tunnel junctions (e.g., Josephson junctions), superconducting quantum interference devices (SQUIDs), inductors, and/or capacitors, etc., and which behave as quantum mechanical anharmonic (non-linear) oscillators with quantized states, when cooled to cryogenic temperatures. A qubit can be effectively operated as a two-level system in a computational subspace comprising a ground state |0 [symbol] and a first excited state |1 [symbol] of the qubit, due to the anharmonicity imparted by a non-linear inductor element (e.g., Josephson junction inductance) of the qubit, which allows the ground and the first excited states to be uniquely addressed at a transition frequency of the qubit, without significantly disturbing higher excited states of the qubit (e.g., |2 [symbol] , |3 [symbol] etc.).

Various types of quantum information processing algorithms can be implemented using a superconducting quantum processor which comprises superconducting qubits which can be coherently controlled, placed into quantum superposition states, exhibit quantum interference effects, and become entangled with one another, by applying various types of quantum gate operations (e.g., single-qubit gate operations, two-qubit gate operations, etc.) to the superconducting qubits. As quantum processors are scaled with increasing numbers of superconducting qubits and higher integration densities, a primary challenge is being able to scale up the number of qubits while coupling/interconnecting qubits without introducing additional channels of noise and unwanted exchange interactions between qubits, which can result in correlated gate errors.

The advent of tunable couplers in superconducting quantum computers for mediating interactions between qubits has led to improved gate operations, e.g., fast and high-fidelity two-qubit gate operations. However, as the number of qubits is scaled, the ability to implement tunable couplers to mediate interactions between pairs of qubits on a quantum chip becomes increasingly problematic and non-trivial to achieve high on/off ratios of qubit-qubit exchange couplings, minimize the effect of flux noise, and to prevent unwanted interactions with spectator qubits, to ensure high-speed and high-fidelity gate operations.

### SUMMARY

Exemplary embodiments of the disclosure include techniques for implementing and utilizing flux-tunable couplers to mediate interactions between quantum bits.

An exemplary embodiment includes a device which comprises a superconducting integrated circuit comprising a tunable coupler. The tunable coupler comprises a first node, a second mode, a first transmon, a second transmon, and a flux-tunable inductive coupler. The first node is coupled to a first quantum bit, and the second node is coupled to a second quantum bit. The first transmon comprises a first Josephson junction, and the second transmon comprises a second Josephson junction. The flux-tunable inductive coupler comprises a superconducting loop that couples the first transmon and the second transmon. The superconducting loop comprises a third Josephson junction. The first Josephson junction, the second Josephson junction, and the third Josephson junction are coupled in series between the first node and the second node of the tunable coupler.

Another exemplary embodiment includes a superconducting integrated circuit comprising a tunable coupler which is configured to modulate interactions between a first quantum bit and a second quantum bit. The tunable coupler comprises a first transmon, a second transmon, and a flux-tunable inductive coupler. The first transmon comprises a first Josephson junction, a second Josephson junction, and a first capacitor having a first capacitor pad. The second transmon comprises a third Josephson junction, a fourth Josephson junction, and a second capacitor having a second capacitor pad. The flux-tunable inductive coupler comprises a superconducting loop that couples the first transmon and the second transmon. The superconducting loop comprises a fifth Josephson junction, the second Josephson junction, and the fourth Josephson junction. The first Josephson junction, the second Josephson junction, and the fifth Josephson junction are coupled in series between the first capacitor pad and the second capacitor pad.

Another exemplary embodiment includes a system which comprises a quantum processor and a control system which is configured to control operation of the quantum processor. The quantum processor comprises a first quantum bit, a second quantum bit, and a tunable coupler coupled to the first quantum bit and the second quantum bit. The tunable coupler comprises a first node, a second node, a first transmon, a second transmon, and a flux-tunable inductive coupler. The first node is coupled to a first quantum bit, and the second node is coupled to a second quantum bit. The first transmon comprises a first Josephson junction, and the second transmon comprises a second Josephson junction. The flux-tunable inductive coupler comprises a superconducting loop that couples the first transmon and the second transmon. The superconducting loop comprises a third Josephson junction. The first Josephson junction, the second Josephson junction, and the third Josephson junction are coupled in series between the first node and the second node of the tunable coupler. The control system is configured to generate a control signal to place the tunable coupler in one of: a first state to enable longitudinal coupling between the first quantum bit and the second quantum bit; and a second state to suppress longitudinal coupling between the first quantum bit and the second quantum bit.

Other embodiments will be described in the following detailed description of exemplary embodiments, which is to be read in conjunction with the accompanying figures.

### BRIEF DESCRIPTION OF THE DRAWINGS

FIG. 1 schematically illustrates a device which comprises a double transmon coupler that is configured to mediate interactions between quantum bits, according to an exemplary embodiment of the disclosure.

FIG. 2 schematically illustrates a device which comprises a double transmon coupler that is configured to mediate interactions between quantum bits, according to another exemplary embodiment of the disclosure.

FIG. 3 schematically illustrates a device which comprises a double transmon coupler that is configured to mediate interactions between quantum bits, according to another exemplary embodiment of the disclosure.

FIGS. 4A, 4B, 4C and 4D depict graphs of simulated curves that show operating characteristics of a double transmon coupler, according to an exemplary embodiment of the disclosure.

FIG. 5 schematically illustrates a qubit array comprising a plurality of qubits and tunable double transmon couplers that are configured to modulate couplings between qubits in the qubit array, according to an exemplary embodiment of the disclosure.

FIG. 6 schematically illustrates a quantum computing system which comprises a quantum processor having an array of superconducting qubits and flux-tunable double transmon couplers to mediate interactions between superconducting qubits, according to an exemplary embodiment of the disclosure.

FIG. 7 schematically illustrates an exemplary architecture of a computing environment for hosting a quantum computing platform and performing quantum information processing, according to an exemplary embodiment of the disclosure.

### DETAILED DESCRIPTION

Exemplary embodiments of the disclosure will now be described in further detail with regard to techniques for implementing and utilizing flux-tunable couplers to mediate interactions between quantum bits. In particular, exemplary embodiments of the disclosure include flux-tunable double transmon couplers which are configured to mediate interactions between quantum bits, while providing high on/off ratios of qubit-qubit couplings (e.g., ZZ coupling), and robustly suppressing sensitivity to flux noise and spectator effects in a superconducting quantum computer, to realize high-speed and high-fidelity gate operations.

For example, an exemplary embodiment of the disclosure includes a device which comprises a superconducting integrated circuit comprising a tunable coupler. The tunable coupler comprises a first node, a second mode, a first transmon, a second transmon, and a flux-tunable inductive coupler. The first node is coupled to a first quantum bit, and the second node is coupled to a second quantum bit. The first transmon comprises a first Josephson junction, and the second transmon comprises a second Josephson junction. The flux-tunable inductive coupler comprises a superconducting loop that couples the first transmon and the second transmon. The superconducting loop comprises a third Josephson junction. The first Josephson junction, the second Josephson junction, and the third Josephson junction are coupled in series between the first node and the second node of the tunable coupler.

In another exemplary embodiment, which may be combined with one or more of the embodiments of the preceding paragraphs, the flux-tunable inductive coupler comprises a radio frequency superconducting quantum interference device.

In another exemplary embodiment, which may be combined with one or more of the embodiments of the preceding paragraphs, the superconducting loop further comprises a fourth Josephson junction and a fifth Josephson junction. In addition, the first transmon comprises a first capacitor which is coupled in parallel with the first Josephson junction and the fourth Josephson junction, and the second transmon comprises a second capacitor which is coupled in parallel with the second Josephson junction and the fifth Josephson junction.

In another exemplary embodiment, which may be combined with one or more of the embodiments of the preceding paragraphs, the superconducting loop further comprises a first superconducting inductor and a second superconducting inductor. In addition, the first transmon comprises a first capacitor which is coupled in parallel with the first Josephson junction and the first superconducting inductor, and the second transmon comprises a second capacitor which is coupled in parallel with the second Josephson junction and the second superconducting inductor.

In another exemplary embodiment, which may be combined with one or more of the embodiments of the preceding paragraphs, the first transmon comprises a first capacitor having a first capacitor pad, and the second transmon comprises a second capacitor having a second capacitor pad. The first capacitor pad, the first Josephson junction, the second Josephson junction, the third Josephson junction, and the second capacitor pad are coupled in series between the first node and the second node of the tunable coupler.

In another exemplary embodiment, which may be combined with one or more of the embodiments of the preceding paragraphs, the device further comprises a control line that is configured to generate a magnetic flux bias which threads through the superconducting loop of the flux-tunable inductive coupler to place the tunable coupler in one of: a first state to enable longitudinal coupling between the first quantum bit and the second quantum bit; and a second state to suppress longitudinal coupling between the first quantum bit and the second quantum bit. A tuning range of a magnitude of the magnetic flux bias between the first state and the second state is greater than about 0.3 magnetic flux quantum.

In another exemplary embodiment, which may be combined with one or more of the embodiments of the preceding paragraphs, the first quantum bit comprises a first transmon quantum bit that is capacitively coupled to the first node of the tunable coupler, and the second quantum bit comprises a second transmon quantum bit that is capacitively coupled to the second node of the tunable coupler.

In another exemplary embodiment, which may be combined with one or more of the embodiments of the preceding paragraphs, the device comprises a quantum processor chip.

Another exemplary embodiment includes a superconducting integrated circuit comprising a tunable coupler which is configured to modulate interactions between a first quantum bit and a second quantum bit. The tunable coupler comprises a first transmon, a second transmon, and a flux-tunable inductive coupler. The first transmon comprises a first Josephson junction, a second Josephson junction, and a first capacitor having a first capacitor pad. The second transmon comprises a third Josephson junction, a fourth Josephson junction, and a second capacitor having a second capacitor pad. The flux-tunable inductive coupler comprises a superconducting loop that couples the first transmon and the second transmon. The superconducting loop comprises a fifth Josephson junction, the second Josephson junction, and the fourth Josephson junction. The first Josephson junction, the second Josephson junction, and the fifth Josephson junction are coupled in series between the first capacitor pad and the second capacitor pad.

In another exemplary embodiment, which may be combined with one or more of the embodiments of the preceding paragraphs, the flux-tunable inductive coupler comprises a radio frequency superconducting quantum interference device.

In another exemplary embodiment, which may be combined with one or more of the embodiments of the preceding paragraphs, the first capacitor pad and the second capacitor pad are coupled to a ground plane, the first Josephson junction and the second Josephson junction are serially connected to and between the first capacitor pad the ground plane, and the third Josephson junction and the fourth Josephson junction are serially connected to and between the second capacitor pad the ground plane.

In another exemplary embodiment, which may be combined with one or more of the embodiments of the preceding paragraphs, the device further comprises a control line that is configured to generate a magnetic flux bias which threads through the superconducting loop of the flux-tunable inductive coupler to place the tunable coupler in either a first state to enable longitudinal coupling between the first quantum bit and the second quantum bit, or a second state to suppress longitudinal coupling between the first quantum bit and the second quantum bit. A tuning range of a magnitude of the magnetic flux bias between the first state and the second state is greater than about 0.3 magnetic flux quantum.

In another exemplary embodiment, which may be combined with one or more of the embodiments of the preceding paragraphs, the first quantum bit comprises a first transmon quantum bit that is capacitively coupled to the first capacitor pad of the first transmon of the tunable coupler, and the second quantum bit comprises a second transmon quantum bit that is capacitively coupled to the second capacitor pad of the second transmon of the tunable coupler.

Another exemplary embodiment includes a system which comprises a quantum processor and a control system which is configured to control operation of the quantum processor. The quantum processor comprises a first quantum bit, a second quantum bit, and a tunable coupler coupled to the first quantum bit and the second quantum bit. The tunable coupler comprises a first node, a second node, a first transmon, a second transmon, and a flux-tunable inductive coupler. The first node is coupled to a first quantum bit, and the second node is coupled to a second quantum bit. The first transmon comprises a first Josephson junction, and the second transmon comprises a second Josephson junction. The flux-tunable inductive coupler comprises a superconducting loop that couples the first transmon and the second transmon. The superconducting loop comprises a third Josephson junction. The first Josephson junction, the second Josephson junction, and the third Josephson junction are coupled in series between the first node and the second node of the tunable coupler. The control system is configured to generate a control signal to place the tunable coupler in one of: a first state to enable longitudinal coupling between the first quantum bit and the second quantum bit; and a second state to suppress longitudinal coupling between the first quantum bit and the second quantum bit.

It is to be understood that the various features shown in the accompanying drawings are schematic illustrations that are not drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the term “exemplary” as used herein means “serving as an example, instance, or illustration.” Any embodiment or design described herein as “exemplary” is not to be construed as preferred or advantageous over other embodiments or designs.

Further, it is to be understood that the phrase “configured to” as used in conjunction with a circuit, structure, element, component, or the like, performing one or more functions or otherwise providing some functionality, is intended to encompass embodiments wherein the circuit, structure, element, component, or the like, is implemented in hardware, software, and/or combinations thereof, and in implementations that comprise hardware, wherein the hardware may comprise quantum circuit elements (e.g., quantum bits, coupling buses, tunable inductive couplers, control circuitry, etc.), discrete circuit elements (e.g., transistors, inverters, etc.), programmable elements (e.g., application specific integrated circuit (ASIC) chips, field-programmable gate array (FPGA) chips, etc.), processing devices (e.g., central processing units (CPUs), graphics processing units (GPUs), etc.), one or more integrated circuits, and/or combinations thereof. Thus, by way of example only, when a circuit, structure, element, component, etc., is defined to be configured to provide a specific functionality, it is intended to cover, but not be limited to, embodiments where the circuit, structure, element, component, etc., is comprised of elements, processing devices, and/or integrated circuits that enable it to perform the specific functionality when in an operational state (e.g., connected or otherwise deployed in a system, powered on, receiving an input, and/or producing an output), as well as cover embodiments when the circuit, structure, element, component, etc., is in a non-operational state (e.g., not connected nor otherwise deployed in a system, not powered on, not receiving an input, and/or not producing an output) or in a partial operational state.

In addition, the term “quantum chip” as used herein refers to a die (e.g., semiconductor die) which comprises a superconducting integrated circuitry comprising various superconducting components such as qubits, tunable couplers, ground planes, signal coplanar waveguides, and resonators, etc. A plurality of dies having the same and/or different configurations of superconducting electronic integrated circuits, can be fabricated on a wafter (e.g., semiconductor wafer), wherein the individual dies can be diced (cut) from the wafer using a die singulation process to provide singulated dies which can be packaged together to construct a modular quantum processor architecture. The terms “quantum chip” and “die” are synonymous terms and used interchangeably herein.

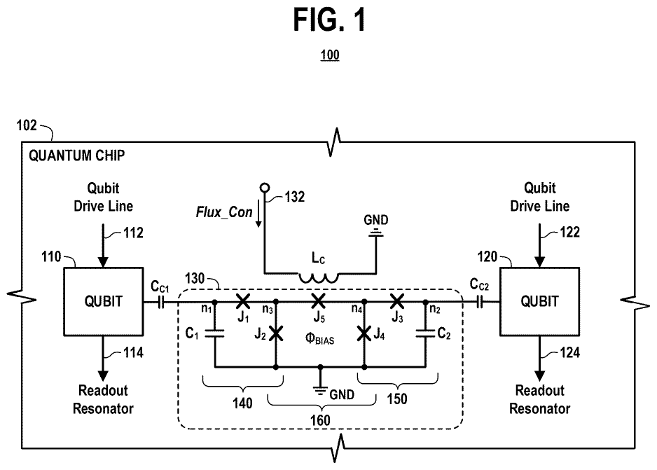

FIG. 1 schematically illustrates a device which comprises a double transmon coupler that is configured to mediate interactions between quantum bits, according to an exemplary embodiment of the disclosure. In particular, FIG. 1 schematically illustrates a device 100 which comprises a quantum chip 102 and superconducting integrated circuitry disposed on the quantum chip 102, wherein the superconducting integrated circuitry comprises, e.g., a first qubit 110, a second qubit 120, and a double transmon coupler 130 which is coupled to and between the first and second qubits 110 and 120. The double transmon coupler 130 comprises a flux-tunable coupler that is configured to mediate interactions (e.g., ZZ interactions) between the first qubit 110 and the second qubit 120, as discussed in further detail below.

The first qubit 110 and the second qubit 120 can be any type of qubit including, but not limited to, superconducting transmon qubits, superconducting fluxonium qubits, superconducting multimode qubits (e.g., superconducting tunable coupler qubits (TCQs)), spin qubits, or other types of qubits that can be capacitively coupled to the double transmon coupler 130 via respective coupling capacitors. As schematically illustrated in FIG. 1, the first qubit 110 is capacitively coupled to a first node n₁ of the double transmon coupler 130 via a first coupling capacitor C_{C1}, and the second qubit 120 is capacitively coupled to a second node n₂ of the double transmon coupler 130 via a second coupling capacitor C_{C2}. In some embodiments, the first qubit 110 and the second qubit 120 comprise fixed-frequency (non-tunable) qubits. In other embodiments, the first qubit 110 and the second qubit 120 comprise flux-tunable qubits with tunable transition frequencies.

The double transmon coupler 130 comprises a first transmon qubit 140 (or first transmon 140), a second transmon qubit 150 (or second transmon 150), and a flux-tunable inductive coupler 160. The first transmon 140 and the second transmon 140 and 150 are fixed-frequency transmon qubits that are coupled through a superconducting loop of the flux-tunable inductive coupler 160. The first transmon 140 comprises a first capacitor C₁, a first Josephson junction J₁, and a second Josephson junction J₂, wherein the first capacitor C₁ is coupled in parallel with the first and second Josephson junctions J₁ and J₂ between the first node n₁ and ground. Similarly, the second transmon 150 comprises a second capacitor C₂, a third Josephson junction J₃, and a fourth Josephson junction J₄, wherein the second capacitor C₂ is coupled in parallel with the third and fourth Josephson junctions J₃ and J₄ between the second node n₂ and ground.

The flux-tunable inductive coupler 160 comprises a superconducting loop which comprises at least one Josephson junction having a non-linear inductance that is modulated by an amount of magnetic flux bias (denoted Φ_{BIAS}) which threads through the superconducting loop, to selectively tune an operating state of the double transmon coupler 130. In some embodiments, such as shown in FIG. 1, the flux-tunable inductive coupler 160 comprises a radio frequency (RF) SQUID which comprises a fifth Josephson junction J₅, the second Josephson junction J₂, and the fourth Josephson junction J₄, wherein the Josephson junctions J₂, J₄, and J₅ form a superconducting loop of the RF SQUID. In the exemplary configuration, the second Josephson junction J₂ is a shared component of the first transmon 140 and the flux-tunable inductive coupler 160, while the fourth Josephson junction J₄ is a shared component of the second transmon 150 and the flux-tunable inductive coupler 160. The first Josephson junction J₁, the fifth Josephson junction J₅, and the third Josephson junction J₃ are serially coupled between the first and second nodes n₁ and n₂ of the double transmon coupler 130.

As schematically illustrated in FIG. 1, the quantum chip 102 further comprises a plurality of control lines including, but not limited to, qubit drive lines 112 and 122, qubit readout resonators 114 and 124, and a flux-bias control line 132. In some embodiments, the qubit drive lines 112 and 122 are coupled (e.g., capacitively coupled) to the first and second qubits 110 and 120, respectively, wherein the qubit drive lines 112 and 122 are configured to apply control signals (e.g., microwave control pulse signals) to independently change the states of the respective first and second qubits 110 and 120. For example, a microwave control pulse can be applied to the qubit drive line 112 to perform a single-qubit gate operation on the first qubit 110 or otherwise modify the computational state of the first qubit 110 as needed when executing a quantum algorithm. Furthermore, a microwave control pulse can be applied to the qubit drive line 122 to perform a single-qubit gate operation on the second qubit 120 or otherwise modify the computational state of the second qubit 120 as needed when executing a quantum algorithm. As is known in the art, the state of a qubit can be changed by applying a microwave control signal (e.g., control pulse) with a center frequency equal to a transition frequency (denoted f₀₁) of the qubit, wherein the transition frequency f₀₁ corresponds to an energy difference between the ground state |0 [symbol] and excited state |1 [symbol] of the qubit. In addition, the axis of rotation about a given axis of the Bloch sphere (e.g., X-axis, Y-axis, or any axis in the X-Y plane) and the amount (angle) of such rotation are based, respectively, on the phase of the microwave control signal, and the amplitude and duration of the microwave control signal.

Further, in some embodiments, the qubit readout resonators 114 and 124 are coupled (e.g., capacitively coupled) to the first and second qubits 110 and 120, respectively, and are utilized to perform dispersive readout operations using known qubit readout techniques. For example, in some embodiments, the qubit readout resonators 114 and 124 comprise transmission line readout resonators (e.g., coplanar waveguide (CPW) resonators) which are configured to have resonant frequencies that are detuned from the respective transition frequencies of respective first and second qubits 110 and 120. In the dispersive regime of qubit-resonator coupling, an RF readout control signal (with the requisite frequency tone, pulse envelope shape, and pulse duration) is applied to a given readout resonator of a given qubit-resonator circuit, and interacts with the given qubit-resonator circuit in a manner which results in the generation of a readout signal that is reflected out from the given readout resonator. The readout signal comprises information (e.g., phase and amplitude information) that is qubit-state dependent. In this regard, a dispersive readout process yields an RF readout signal having a state-dependent phasor response, which is analyzed to discriminate the quantum state of the given qubit, e.g., determine whether the readout state of the given qubit is the ground state |0 [symbol] or the first excited state |1 [symbol] , wherein for readout, a superposition state of the given qubit is projected onto the ground state |0 [symbol] or the first excited state |1 [symbol] , as is known in the art.

The double transmon coupler 130 is operatively controlled by a control system which generates and outputs a flux-bias control signal (denoted Flux_Con) on the flux-bias control line 132 to mediate interactions between the first and second qubits 110 and 120. The flux-bias control signal Flux_Con is configured to cause the double transmon coupler 130 to modulate a coupling strength (e.g., ZZ coupling) between the first and second qubits 110 and 120 and thereby tune the double transmon coupler 130 into different operating states including a first state (or “ON state”) and a second state (or “OFF state”). As schematically illustrated in FIG. 1, the flux-tunable inductive coupler 160 of the double transmon coupler 130 is disposed in proximity to a coupling inductor L_{C} which is connected in series (inline) with the flux-bias control line 132. In some embodiments, the flux-bias control signal Flux_Con comprises a current signal that is applied to the coupling inductor L_{C} to generate a magnetic flux (denoted Φ_{BIAS}) which threads through the superconducting loop of the flux-tunable inductive coupler 160 to modulate an inductive coupling between the first and second transmons 140 and 150 and place the double transmon coupler 130 into a desired operating state, e.g., ON state or OFF state.

In the ON state, the double transmon coupler 130 enables a longitudinal coupling (e.g., ZZ coupling) between the first and second qubits 110 and 120 to facilitate fast two-qubit gate and entanglement operations. For example, a two-qubit gate operation can be, e.g., a controlled-phase gate operation (CPHASE gate) in which a phase shift is applied to a target qubit when a control qubit is in a first excited state |1 [symbol] . In other embodiments, when the first and second qubits 110 and 120 are close in frequency, the two-qubit gate operation can be a SWAP gate operation in which the state of the first qubit 110 becomes the state of the second qubit 120, and vice versa. The double transmon coupler 130 can be utilized to perform other types of parametric entanglement gate operations.

On the other hand, in the OFF state, the double transmon coupler 130 substantially suppresses the longitudinal coupling (e.g., ZZ coupling) between the first and second qubits 110 and 120 and thereby decouples the first and second qubits 110 and 120. In the OFF state of the double transmon coupler 130, the residual ZZ coupling strength between the first and second qubits 110 and 120 is substantially zero or negligibly small. With the double transmon coupler 130 tuned in the OFF state, a single-qubit gate operation can be applied to a given one of the first qubit 110 or the second qubit 120 to individually change the state of the given qubit without perturbing the state of the other qubit since the ZZ coupling between the first and second qubits 110 and 120 is significantly suppressed.

In an exemplary embodiment, the double transmon coupler 130 comprises a first coupler mode which is associated with a mode of the first transmon 140, and a second coupler mode which is associated with a mode of the second transmon 150. The double transmon coupler 130 is tuned into an ON state by the control system applying a flux-bias control signal Flux_Con to the flux-bias control line 132 to generate a first amount of magnetic flux bias Φ_{Bias} which causes the modes of the first and second transmons 140 and 150 to hybridize which, in turn, causes one of the coupler modes (first coupler mode or second coupler mode) to move in frequency towards the transition frequencies of the first and second qubits 110 and 120. The mode hybridization results in a strong exchange coupling between the coupler mode and the first and second qubits 110 and 120 and, consequently, an increase in the longitudinal interaction (ZZ interaction) between the first and second qubits 110 and 120 through the double transmon coupler 130.

On the other hand, the double transmon coupler 130 is tuned into an OFF state by the control system applying a flux-bias control signal Flux_Con to the flux-bias control line 132 to generate a second amount of magnetic flux bias Φ_{Bias} which does not cause the modes of the first and second transmons 140 and 150 to hybridize with each other, such that the first and second coupler modes remain degenerate (e.g., the first and second coupler modes have the same or substantially the same frequency) and are detuned far from the transition frequencies of the first and second qubits 110 and 120. As noted above, with the double transmon coupler 130 in an OFF state, the longitudinal coupling (or residual ZZ coupling) between the first and second qubits 110 and 120 is significantly suppressed.

The level of magnetic flux bias Φ_{Bias} which is needed to place the double transmon coupler 130 in an OFF state or an ON state will depend on whether the frequencies of the normal (degenerate) coupler modes (or non-hybridized modes of the first and second transmons 140 and 150) are below or above the transition frequencies of the first and second qubits 110 and 120. For example, in an exemplary embodiment where the frequencies of the normal (degenerate) coupler modes are below the transition frequencies of the first and second qubits 110 and 120, the double transmon coupler 130 is placed in in OFF state when the amount of magnetic flux bias ΦBias (which threads through the superconducting loop of the flux-tunable inductive coupler 160) has a magnitude of Φ_{BIAS}=x Φ₀, where 0.25<x<0.5, and where Φ₀ denotes the magnetic flux quantum

$${Φ}_{0} = \frac{h}{2 e}$$

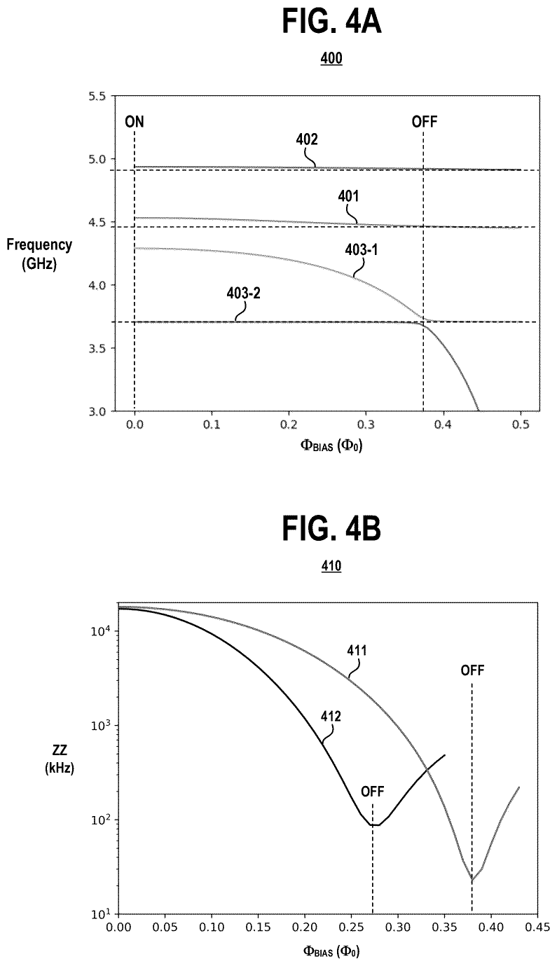

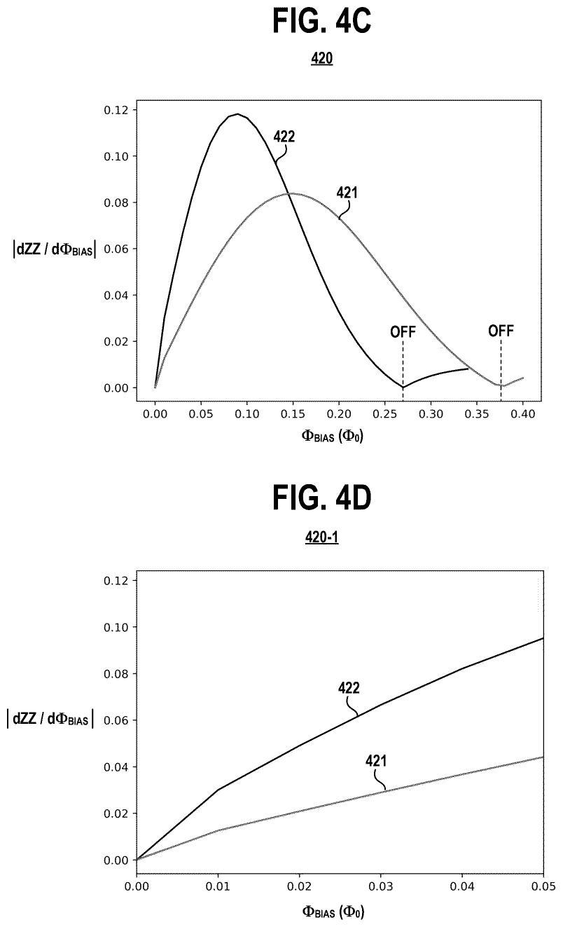

(where h denotes the Planck constant and e denotes the elementary charge constant). For example, in an exemplary non-limiting embodiment as discussed in further detail below in conjunction with FIG. 4A, the double transmon coupler 130 is tuned into an OFF state by applying a flux-bias control signal Flux_Con to the control line 132 which results in a magnetic flux bias of Φ_{BIAS}≈0.375 Φ₀ threading through the superconducting loop of the flux-tunable inductive coupler 160. On the other hand, the double transmon coupler 130 is placed into an ON state by decreasing the amount of magnetic flux bias Φ_{Bias} threading through the superconducting loop of the flux-tunable inductive coupler 160 to a level of Φ_{BIAS}≈0.

It is to be appreciated that the exemplary double transmon couplers as described herein are configured to provide strongly tunable interactions between qubits, while providing broadband suppression of interactions with spectator qubits. In addition, as compared to conventional double transmon coupler architectures, the exemplary double transmon couplers as disclosed herein provide wider tuning ranges (e.g., wider range of Φ_{BIAS}) between the ON and OFF states, which advantageously provide less sensitivity to flux noise. A conventional double transmon coupler traditionally has more sensitivity to flux noise than a coupler based on a single transmon because the qubit-to-qubit interaction of a double transmon couple turns on more quickly than with a single transmon coupler, For example, a conventional double transmon coupler has a tuning range of approximately 0.25 Φ₀ between the ON and OFF states of the double transmon coupler, while a single transmon coupler can be designed to have a tuning range of approximately 0.50 Φ₀ between the ON and OFF states of the single transmon coupler. However, the tuning range of 0.25 Φ₀ between the ON and OFF states of the conventional double transmon coupler leads to increased sensitivity to flux noise.

For example, a conventional double transmon coupler has an architecture which is similar to the exemplary architecture of the double transmon coupler 130 as shown in FIG. 1. However, the conventional double transmon coupler does not include the additional Josephson junctions J₁ and J₃, which are serially coupled with the Josephson junction J₅ of the flux-tunable inductive coupler 160. The exemplary architecture of the double transmon coupler 130 as shown in FIG. 1 includes the additional Josephson junctions J₁ and J₃ such that the constituent first and second transmons 140 and 150 each comprise two Josephson junctions instead of only one Josephson junction. In this configuration, the total Josephson energy for the first transmon 140 is split between the two Josephson junctions J₁ and J₂, and the total Josephson energy for the second transmon 150 is split between the two Josephson junctions J₃ and J₄, which alters (increases) the tuning range of the inductive coupling between the first and second transmons 140 and 150 by the flux-tunable inductive coupler 160 (e.g., RF-SQUID). For example, while a conventional double transmon coupler has a tuning range of ~0.25 Φ₀ between the ON and OFF states, the exemplary double transmon coupler 130 of FIG. 1 can be configured to have a tuning range which is greater than 0.25 Φ₀, thereby providing less sensitivity to flux noise.

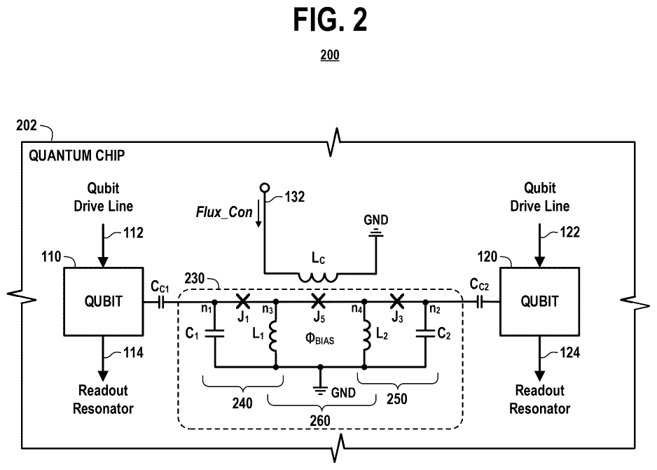

FIG. 2 schematically illustrates a device which comprises a double transmon coupler that is configured to mediate interactions between quantum bits, according to another exemplary embodiment of the disclosure. In particular, FIG. 2 schematically illustrates a device 200 which comprises a quantum chip 202 with superconducting integrated circuitry disposed on the quantum chip 202, wherein the superconducting circuitry is similar in circuit architecture and function as the various superconducting circuitry of the quantum chip 102 as shown in FIG. 1. However, FIG. 2 illustrates another exemplary architecture of a double transmon coupler 230 which may be coupled to and between the first and second qubits 110 and 120 and configured to mediate interactions (e.g., ZZ interactions) between the first qubit 110 and the second qubit 120, as discussed above.

Similar to the architecture of the double transmon coupler 130 of FIG. 1, the double transmon coupler 230 of FIG. 2 comprises a first transmon qubit 240 (or first transmon 240), a second transmon qubit 250 (or second transmon 250), and a flux-tunable inductive coupler 260, wherein the first and second transmons 240 and 250 are fixed-frequency transmon qubits that are coupled through a superconducting loop of the flux-tunable inductive coupler 260. In contrast to the double transmon coupler 130 of FIG. 1, the double transmon coupler 230 of FIG. 2 implements a first inductor L₁ and a second inductor L₂ in place of the Josephson junctions J₂ and J₄, respectively. The first and second inductors L₁ and L₂ comprise superconducting inductors with fixed/linear inductances. The double transmon coupler 230 operates in the same or similar manner as the double transmon coupler 130 of FIG. 1 as discussed above, the details of which need not be repeated.

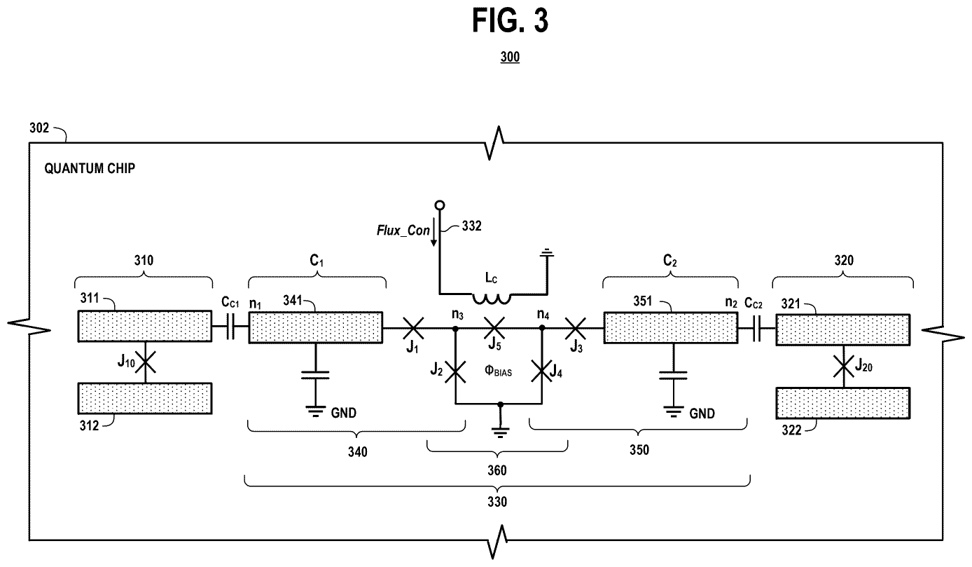

FIG. 3 schematically illustrates a device which comprises a double transmon coupler that is configured to mediate interactions between quantum bits, according to another exemplary embodiment of the disclosure. In particular, FIG. 3 schematically illustrates a device 300 which comprises a quantum chip 302 and superconducting integrated circuitry disposed on the quantum chip 302, wherein the superconducting integrated circuitry comprises, e.g., a first qubit 310, a second qubit 320, a double transmon coupler 330, a flux-bias control line 332, and a coupling inductor L_{C}. The double transmon coupler 330 comprises a first transmon qubit 340 (or first transmon 340), a second transmon qubit 350 (or second transmon 350), and a flux-tunable inductive coupler 360. The double transmon coupler 330 comprises a flux-tunable coupler that is configured to mediate interactions (e.g., ZZ interactions) between the first qubit 310 and the second qubit 320, using the same or similar tuning methods as discussed herein.

FIG. 3 schematically illustrates an exemplary architecture of the double transmon coupler 330 which is based on the schematic circuit architecture of the double transmon coupler 130 of FIG. 1, but where FIG. 3 illustrates an exemplary planar circuit configuration of the first and second capacitors C₁ and C₂ of the respective first and second transmons 340 and 350 of the double transmon coupler 330. In particular, as schematically illustrated in FIG. 3, the first capacitor C₁ of the first transmon 340 comprises a superconducting pad 341 (or superconducting capacitor pad 341) that is capacitively coupled to ground GND (e.g., a ground plane) to provide a capacitance which is coupled in parallel with the first and second Josephson junctions J₁ and J₂ of the first transmon 340. Similarly, the second capacitor C₂ of the second transmon 350 comprises a superconducting pad 351 (or superconducting capacitor pad 351) that is capacitively coupled to ground GND to provide a capacitance which is coupled in parallel with the third and fourth Josephson junctions J₃ and J₄ of the second transmon 350.

In addition, FIG. 3 schematically illustrates an exemplary planar circuit configuration of the first and second qubits 310 and 320, wherein the first and second qubits 310 and 320 comprise fixed-frequency superconducting transmon qubits. In general, a transmon qubit comprises a Josephson junction and capacitor that are connected in parallel, wherein the Josephson junction functions as a non-linear inductor which, when shunted with the capacitor, forms an anharmonic LC oscillator with individually addressable energy levels (e.g., two lowest energy levels corresponding to the ground state |0 [symbol] and the first excited state |1 [symbol] ).

In particular, as schematically illustrated in FIG. 3, the first qubit 310 comprises a first superconducting pad 311, a second superconducting pad 312, and a Josephson junction J₁₀ that is coupled to, and disposed between, the first and second superconducting pads 311 and 312. The first and second superconducting pads 311 and 312 comprise superconducting capacitor electrodes of a coplanar capacitor structure which is connected in parallel with the Josephson junction J₁₀ to form a transmon-type qubit. The first qubit 310 is coupled to the first node n₁ of the double transmon coupler 330 by capacitively coupling (via a coupling capacitor C_{C1}) the first superconducting pad 311 of the first qubit 310 and the superconducting pad 341 of the first transmon 340.

Similarly, the second qubit 320 comprises a first superconducting pad 321, a second superconducting pad 322, and a Josephson junction J₂₀ that is coupled to, and disposed between, the first and second superconducting pads 321 and 322. The first and second superconducting pads 321 and 322 comprise superconducting capacitor electrodes of a coplanar capacitor structure which is connected in parallel with the Josephson junction J₂₀ to form a transmon-type qubit. The second qubit 320 is coupled to the second node n₂ of the double transmon coupler 330 by capacitively coupling (via a coupling capacitor C_{C2}) the first superconducting pad 321 of the second qubit 320 and the superconducting pad 351 of the second transmon 350. The first and second coupling capacitors C_{C1} and C_{C2} can be implemented using suitable capacitive coupling structures and techniques known to those of ordinary skill in the art.

FIGS. 4A, 4B, 4C and 4D illustrate graphs of simulated curves which show operating characteristics of a double transmon coupler, according to an exemplary embodiment of the disclosure. For illustrative purposes, FIGS. 4A, 4B, 4C and 4D depict simulated operating characteristics of a double transmon coupler having a circuit architecture which is based, for example, on the exemplary embodiments of FIGS. 1 and 3, wherein (i) the first and second qubits are modeled as transmon qubits comprising transition frequences in a range of 4.50 GHz to 5.0 GHz, (ii) the OFF-state frequency of the double transmon coupler is about 3.50-4.0 GHz (which is below the transition frequencies of the transmon qubits), and (iii) the exchange couplings between the double transmon coupler and each transmon qubit is 100 MHz.

For example, FIG. 4A illustrates a graph 400 of simulated curves which show mode frequencies (Y-axis) of first and second qubits, and of a double transmon coupler (which mediates ZZ coupling between the first and second qubits), as a function of a magnetic flux bias Φ_{BIAS}=xΦ₀ (X-axis) over a range of 0≤x≤0.5, which is applied to the double transmon coupler. More specifically, the graph 400 depicts (i) a simulated curve 401 which represents a mode frequency of the first transmon qubit having a transition frequency f₀₁ of ~4.5 GHZ, (ii) a simulated curve 402 w which represents a mode frequency of the second transmon qubit having a transition frequency f₀₁ of ~4.9 GHZ, (iii) a simulated curve 403-1 which represents a first mode frequency (or first coupler mode) of the double transmon coupler, and (iv) a simulated curve 403-2 which represents a second mode frequency (or second coupler mode) of the double transmon coupler. In an exemplary embodiment, the simulated curves 403-1 and 403-2 represents mode frequencies (as a function of magnetic flux bias Φ_{Bias}) of a first transmon and a second transmon, respectively, of the double transmon coupler.

The simulated curves 403-1 and 403-1 represent either symmetric or antisymmetric combinations of the modes of the first and second transmons of the double transmon coupler, wherein one of those combinations will be affected by a change in the inductive coupling between the first and second transmons, while the other is not affected by the change in the inductive coupling. In particular, FIG. 4A illustrates an exemplary OFF state of the double transmon coupler which is achieved by applying a magnetic flux bias Φ_{Bias} of ~0.375 Φ₀ to the flux-tunable inductive coupler (e.g., RF-SQUID) of the double transmon coupler. In the OFF state, the modes of the first and second transmons of the double transmon coupler do not hybridize with each other, and the first and second coupler modes are degenerate. As illustrated in FIG. 4A, the OFF state of the double transmon coupler represents a point at which the simulated curves 403-1 and 403-2 meet where the first and second coupler modes are at substantially the same mode frequency of ~3.70 GHz, which is detuned far from the transition frequencies of the first and second transmon qubits. The OFF state represents a state in which there is minimum coupling between the first and second transmons of the double transmon coupler. As noted above, with the double transmon coupler in an OFF state, the longitudinal coupling (or ZZ coupling) between the first and second transmon qubits is significantly suppressed.

In addition, FIG. 4A illustrates an exemplary ON state of the double transmon coupler which is achieved by applying a magnetic flux bias Φ_{Bias}=0 to the flux-tunable inductive coupler (e.g., RF-SQUID) of the double transmon coupler. The ON state of the double transmon coupler represents a state in which there is significantly strong coupling between the first and second transmons of the double transmon coupler, which causes the normal modes of the first and second transmons to hybridize. In particular, the simulated curves 403-1 and 403-2 of FIG. 4A illustrate that as the magnetic flux bias Φ_{Bias} moves toward zero (0) magnetic flux quantum (from the OFF state to the ON state), the first and second coupler modes hybridize, wherein one of the hybridized coupler modes (e.g., the first coupler mode of simulated curve 403-1) moves up in frequency toward the transition frequencies of the first and second transmon qubits. The coupler mode hybridization results in a strong exchange coupling between the first coupler mode (curve 403-1) and the modes of the first and second transmon qubits which, in turn, increases in the longitudinal coupling (ZZ coupling) between the first and second transmon qubits through the double transmon coupler. As further shown in FIG. 4A, because of the strong exchange coupling between the hybridized coupler mode and the first and second transmon qubits, the transition frequencies of the transmon qubits slightly increase as the double transmon coupler is tuned from the OFF state to the ON state.

As noted above, with a conventional double transmon coupler, the Φ_{BIAS} tuning range between the ON and OFF states would be ~0.25 Φ₀. In contrast, the simulated curves 403-1 and 403-2 of FIG. 4A illustrate that an exemplary double transmon coupler having first and second transmons with additional series Josephson junctions (e.g., Josephson junctions J₁ and J₃ as shown in FIGS. 1, 2, and 3) increases the Φ_{BIAS} tuning range between the ON and OFF states to ~0.375 Φ₀ (e.g, Φ_{BIAS}=0 for ON state, and Φ_{BIAS}~0.375 Φ₀ for OFF state). In other words, as compared to a conventional double transmon coupler, an exemplary double transmon coupler with the additional series Josephson junctions (e.g., Josephson junctions J₁ and J₃) results in a wider ØBIAS tuning range between the ON and OFF states of the double transmon coupler such that the longitudinal coupling between the first and second qubits turns on and off more gradually, which makes the flux-bias control of the double transmon coupler less sensitive to flux noise.

Next, FIG. 4B illustrates a graph 410 of simulated curves which comparatively illustrate a longitudinal coupling (or ZZ coupling) between first and second qubits as a function of a magnetic flux bias Φ_{Bias} that is applied to a conventional double transmon coupler, and to a double transmon coupler according to an exemplary embodiment of the disclosure. In particular, the graph 410 illustrates (i) a simulated curve 411 which represents a magnitude of ZZ coupling between first and second qubits as function of magnetic flux bias Φ_{Bias} applied to an exemplary double transmon coupler architecture having additional series Josephson junctions (e.g., Josephson junctions J₁ and J₃), and (ii) a simulated curve 412 which represents a magnitude of ZZ coupling between first and second qubits as function of magnetic flux bias Φ_{Bias} applied to a conventional double transmon coupler which does not implement the additional series Josephson junctions (e.g., Josephson junctions J₁ and J₃).

The simulated curves 411 and 412 show that in the ON state, the double transmon couplers provide a same maximum ZZ coupling (e.g., ~20 MHz) between the first and second qubits. In addition, the simulated curve 412 shows that in the OFF state, the conventional double transmon coupler provides a minimal ZZ coupling between the first and second qubits when the conventional double transmon coupler is flux-tuned with a magnetic flux bias Φ_{BIAS}~0.275 Φ₀. Moreover, the simulated curve 411 shows that in the OFF state, an exemplary double transmon coupler having the additional series Josephson junctions (e.g., Josephson junctions J₁ and J₃), provides a minimal ZZ coupling between the first and second qubits when the double transmon coupler is flux-tuned with a magnetic flux bias Φ_{BIAS}~0.375 Φ₀. In addition, the simulated curves 411 and 412 show that in the OFF state, as compared to the conventional double transmon coupler architecture, the exemplary double transmon coupler architecture having the additional series Josephson junctions (e.g., Josephson junctions J₁ and J₃) provides a greater suppression of ZZ coupling between the first and second qubits.

Next, FIG. 4C illustrates a graph 420 of simulated curves which comparatively illustrate flux noise sensitivity of a conventional double transmon coupler and a double transmon coupler according to an exemplary embodiment of the disclosure. In particular, the graph 420 of simulated curves shows a sensitivity of longitudinal (ZZ) coupling based on a computed derivative

$$\frac{dZZ}{d {Φ}_{BIAS}}$$

(Y-axis) as a function of magnetic flux bias Φ_{BIAS}=x Φ₀ (X-axis) over a range of 0=x=0.40. The graph 420 illustrates (i) a simulated curve 421 which represents a computed derivative

$$\frac{dZZ}{d {Φ}_{BIAS}}$$

of ZZ coupling between first and second qubits as function of magnetic flux bias Φ_{Bias} applied to an exemplary double transmon coupler architecture having additional series Josephson junctions (e.g., Josephson junctions J₁ and J₃), and (ii) a simulated curve 423 which represents a computed derivative

$$\frac{dZZ}{d {Φ}_{BIAS}}$$

of ZZ coupling between first and second qubits as function of magnetic flux bias Φ_{Bias} applied to a conventional double transmon coupler which does not implement the additional series Josephson junctions (e.g., Josephson junctions J₁ and J₃). The simulated curves 421 and 422 show that in comparison to a conventional double transmon coupler architecture, the exemplary double transmon coupler architecture with additional series Josephson junctions (e.g., Josephson junctions J₁ and J₃) has smaller values

$$\frac{dZZ}{d {Φ}_{BIAS}}$$

over the exemplary magnetic flux bias tuning range and, consequently, is less sensitive to flux noise than the conventional double transmon coupler.

Next, FIG. 4D illustrates a graph 420-1 which depicts a portion of the simulated curves 421 and 422 of FIG. 4C over a truncated range of magnetic flux bias Φ_{Bias}, i.e., from Φ_{Bias}=0 to Φ_{Bias}=0.05. In particular, FIG. 4D depicts portion of the simulated curves 421 and 422 at or near the ON state of the double transmon couplers, which represent a critical area near Φ_{Bias}=0 where the ZZ coupling is maximum. The simulated curves 421 and 422 in FIG. 4D show that the conventional double transmon coupler (curve 422) is about 2× more sensitive to flux noise near the ON state region, as compared to an exemplary double transmon coupler architecture having the additional series Josephson junctions (e.g., Josephson junctions J₁ and J₃), such as shown in FIG. 1, 2, or 3.

It is to be noted that FIGS. 4A, 4B, 4C and 4D illustrate an exemplary embodiment in which the normal mode frequencies of the first and second transmons of the double transmon coupler are below the transition frequencies of the first and second qubits, wherein the double transmon coupler is flux-biased into an ON state by causing the normal modes of the first and second transmons of the double transmon coupler to be hybridized such that one of the hybridized modes of the double transmon coupler increases in frequency towards the transition frequencies of the first and second qubits. However, in other embodiments, the double transmon coupler can be configured where the normal mode frequencies of the first and second transmons of the double transmon coupler are above the transition frequencies of the first and second qubits, wherein the double transmon coupler is flux-biased into an ON state by causing the normal modes of the first and second transmons of the double transmon coupler to be hybridized such that one of the hybridized modes of the double transmon coupler decreases in frequency towards the transition frequencies of the first and second qubits.

In this regard, it is be noted that the coupler modes of the double transmon coupler and the transition frequencies of the first and second qubits can be set by, e.g., engineering critical currents of the Josephson junctions of the data qubits, and the first and second transmons of the double transmon coupler. In addition, the critical currents of the Josephson junctions of the transmons and the flux-tunable inductive coupler (e.g. RF-SQUID) of the double transmon coupler are engineered to ensure that the there is sufficient tuning range to move the coupler frequency towards the transition frequencies of the data qubits to turn ON the double transmon coupler and provide sufficient longitudinal coupling between the data qubits. For example, in the exemplary embodiments of FIGS. 1 and 2, the characteristics of the Josephson junction J₅ of the flux-tunable inductive coupler (e.g., RF-SQUID) can be optimized to provide desired tuning properties to flux tune the double transmon coupler into an ON state to perform fast and high-fidelity two-qubit gate operations, while minimizing the sensitivity of the double transmon coupler to flux noise, as discussed above.

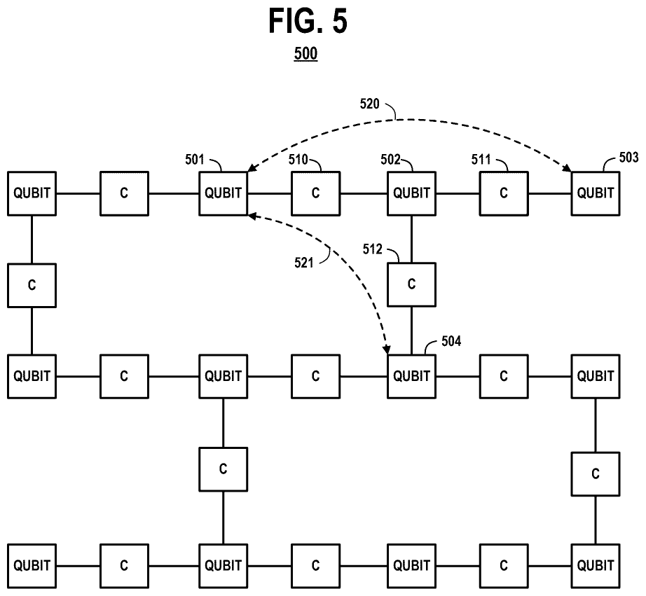

It is to be appreciated that the exemplary double transmon coupler architectures as discussed herein are configured to provide high suppression of residual ZZ interactions between data qubits that are directly coupled to a given double transmon coupler, as well as eliminate or significantly suppressing stray/spurious coupling (e.g., NNN coupling) to/from spectator qubits in a qubit lattice. FIG. 5 schematically illustrates a qubit array comprising a plurality of qubits and tunable double transmon couplers that are configured to modulate couplings between qubits in the qubit array, according to an exemplary embodiment of the disclosure. In particular, FIG. 5 schematically illustrates a qubit array 500 (or qubit lattice 500) which comprises a plurality of data qubits (each labeled QUBIT) and a plurality of flux-tunable double transmon couplers (each labeled C) to modulate the coupling between neighboring data qubits.

By way of example, FIG. 5 includes data qubits 501, 502, 503, and 504 (e.g., transmon qubits), and flux-tunable double transmon couplers 510, 511, and 512 which are implemented using an exemplary double transmon coupler architecture such as shown in FIG. 1, 2, or 3, as described above. In the exemplary embodiment of FIG. 5, the flux-tunable double transmon coupler 510 is configured to modulate a coupling between the neighboring data qubits 501 and 502, the flux-tunable double transmon coupler 511 is configured to modulate a coupling between the neighboring data qubits 502 and 503, and the flux-tunable double transmon coupler 512 is configured to modulate a coupling between the neighboring data qubits 502 and 504.

FIG. 5 schematically illustrates an undesirable circumstance in which the data qubit 503 and/or the data qubit 504 can be spectator qubits whose quantum states and/or transition frequencies are perturbed or otherwise adversely affected through respective stray couplings 520 and 521 with the data qubit 501, which can adversely affect the fidelity of an entanglement gate operations or otherwise lead to other spectator errors. The flux-tunable double transmon couplers 510, 511, and 512, however, are configured to eliminate or otherwise significantly suppress any stray coupling or crosstalk between the data qubits 501, 503, and 504 when, e.g., the flux-tunable double transmon coupler 510 is turned ON to couple the data qubits 501 and 502 and perform an entanglement gate operation. Indeed, as noted above, flux-tunable double transmon couplers (C) in the qubit array 500 allow enhanced coupling of direct qubit neighbors while eliminating stray coupling (e.g., NNN coupling) with spectator qubits. The flux-tunable double transmon couplers (C) in the qubit array 500 allow an increase in the number of neighbors that each data qubit can have in the qubit array 500, while eliminating stray couplings that can lead to spectator induced errors. Advantageously, the exemplary flux-tunable double transmon couplers as discussed herein facilitate the creation of a quantum computer with suppressed crosstalk between qubits and suppressed spectator errors.

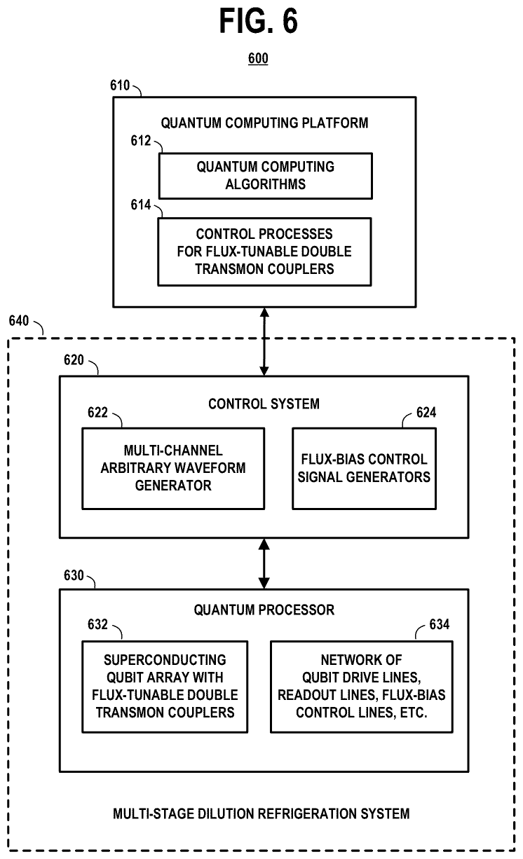

FIG. 6 schematically illustrates a quantum computing system which comprises a quantum processor having an array of superconducting qubits and flux-tunable double transmon couplers to mediate interactions between superconducting qubits, according to an exemplary embodiment of the disclosure. In particular, FIG. 6 schematically illustrates a quantum computing system 600 which comprises a quantum computing platform 610, a control system 620, and a quantum processor 630 (or quantum processing unit (QPU)). In some embodiments, the quantum computing platform 610 implements a software platform that is configured to program a quantum computer to execute quantum computing algorithms 612 which are implemented using, e.g., quantum circuits that define computational routines consisting of coherent quantum operations on quantum data, such as qubits. In addition, in some embodiments, the quantum computing platform 610 implements software control processes 614 to control and synchronize the generation of flux-bias control signals for controlling the operation of flux-tunable double transmon couplers.

In some embodiments, the control system 620 comprises a multi-channel arbitrary waveform generator 622, and flux-bias control signal generators 624. The quantum processor 630 comprises one or more solid-state quantum chips which collectively implement a superconducting qubit array 632 comprising a plurality of flux-tunable double transmon couplers that are configured to couple pairs of qubits. The quantum processor 630 implements a network 634 of qubit drive lines, readout resonator lines, flux-bias control lines, etc., and other circuit QED components that may be needed for a given application or quantum system configuration.

In some embodiments, the control system 620 and the quantum processor 630 are disposed at different stages of a dilution refrigeration system 640 which can generate cryogenic temperatures that are sufficient to operate components of the control system 620 for quantum computing applications. For example, the quantum processor 630 may need to be cooled down to near-absolute zero, e.g., 10-15 millikelvin (mK), to allow the superconducting qubits and the flux-tunable double transmon couplers to exhibit quantum behaviors. In some embodiments, the dilution refrigeration system 640 comprises a multi-stage dilution refrigerator where the components of the control system 620 can be maintained at different cryogenic temperatures, as needed. For example, while the quantum processor 630 may need to be cooled down to, e.g., 10-15 mK, the circuit components of the control system 620 may be operated at cryogenic temperatures greater than 10-15 mK (e.g., cryogenic temperatures in a range of 3K-4K), depending on the configuration of the quantum computing system. In other embodiments, some or all of the components of the control system 620 are disposed and operated in a room temperature environment.

In some embodiments, the superconducting qubit array 632 comprises a quantum system of superconducting qubits, superconducting double transmon couplers, and other components commonly utilized to support quantum processing using qubits. The number of superconducting qubits of the superconducting qubit array 632 can be on the order of tens, hundreds, thousands, or more, etc. The network 634 of qubit drive lines, readout resonator lines, and flux-bias control lines, etc., is coupled to the control system 620 through a suitable hardware input/output (I/O) interface, which couples I/O and control signals between the control system 620 and the quantum processor 630. For example, the hardware I/O interface may comprise various types of hardware and components, such as RF cables, wiring, RF elements, optical fibers, heat exchanges, filters, amplifiers, isolators, etc.

In some embodiments, the multi-channel AWG 622 and other suitable microwave pulse signal generators are configured to generate the microwave control pulses that are applied to the qubit drive lines to control the operation of the superconducting qubits when performing various gate operations to execute a given certain quantum information processing algorithm. The multi-channel AWG 622 generates and selectively applies microwave control pulses to the qubit drive lines of respective superconducting qubits to change the quantum state of the superconducting qubits (e.g., change the quantum state of a given qubit between the ground state and excited state, or to a superposition state) when executing quantum information processing algorithms. In addition, the flux-bias control signal generators 624 generate flux-bias control signals that are applied to flux-bias control lines to selectively activate/deactivate the flux-tunable double transmon couplers to perform multi-gate entanglement operations (e.g., two qubit gate operations) when executing quantum information processing algorithms.

In some embodiments, the multi-channel AWG 622 comprises a plurality of AWG channels, which control respective superconducting qubits within the superconducting qubit array 632 of the quantum processor 630. In some embodiments, each AWG channel comprises a baseband signal generator, a digital-to-analog converter (DAC) stage, a filter stage, a modulation stage, an impedance matching network, and a phase-locked loop system to generate local oscillator (LO) signals (e.g., quadrature LO signals LO_I and LO_Q) for the respective modulation stages of the respective AWG channels. In some embodiments, the multi-channel AWG 622 comprises a quadrature AWG system which is configured to process quadrature signals, wherein a quadrature signal comprises an in-phase (I) signal component, and a quadrature-phase (Q) signal component. In each AWG channel the baseband signal generator is configured to receive baseband data as input (e.g., from the quantum computing platform), and generate digital quadrature signals I and Q which represent the input baseband data. In this process, the baseband data that is input to the baseband signal generator for a given AWG channel is separated into two orthogonal digital components including an in-phase (I) baseband component and a quadrature-phase (Q) baseband component. The baseband signal generator for the given AWG channel will generate the requisite digital quadrature baseband IQ signals which are needed to generate an analog waveform (e.g., sinusoidal voltage waveform) with a target center frequency that is configured to operate or otherwise control a given quantum bit that is coupled to the output of the given AWG channel.

The DAC stage for the given AWG channel is configured to convert a digital baseband signal (e.g., a digital IQ signal output from the baseband signal generator) to an analog baseband signal (e.g., analog baseband signals I(t) and Q(t)) having a baseband frequency. The filter stage for the given AWG channel is configured to filter the IQ analog signal components output from the DAC stage to thereby generate filtered analog IQ signals. The modulation stage for the given AWG channel is configured to perform analog IQ signal modulation (e.g., single-sideband (SSB) modulation) by mixing the filtered analog signals I(t) and Q(t), which are output from the filter stage, with quadrature LO signals (e.g., an in-phase LO signal (LO_I) and a quadrature-phase LO signal (LO_Q)) to generate and output an analog RF signal (e.g., a single-sideband modulated RF output signal).

The quantum computing platform 610 comprises a software and hardware platform which comprises various software layers that are configured to perform various functions, including, but not limited to, generating and implementing various quantum applications using suitable quantum programming languages, configuring and implementing various quantum gate operations, compiling quantum programs into a quantum assembly language, implementing and utilizing a suitable quantum instruction set architecture (ISA), performing calibration operations to calibrate the quantum circuit elements and gate operations, etc. In addition, the quantum computing platform 610 comprises a hardware architecture of processors, memory, etc., which is configured to control the execution of quantum applications, and interface with the control system 620 to (i) generate digital control signals that are converted to analog microwave control signals by the control system 620, to control operations of the quantum processor 630 when executing a given quantum application, and (ii) to obtain and process digital signals received from the control system 620, which represent the processing results generated by the quantum processor 630 when executing various gate operations for a given quantum application.

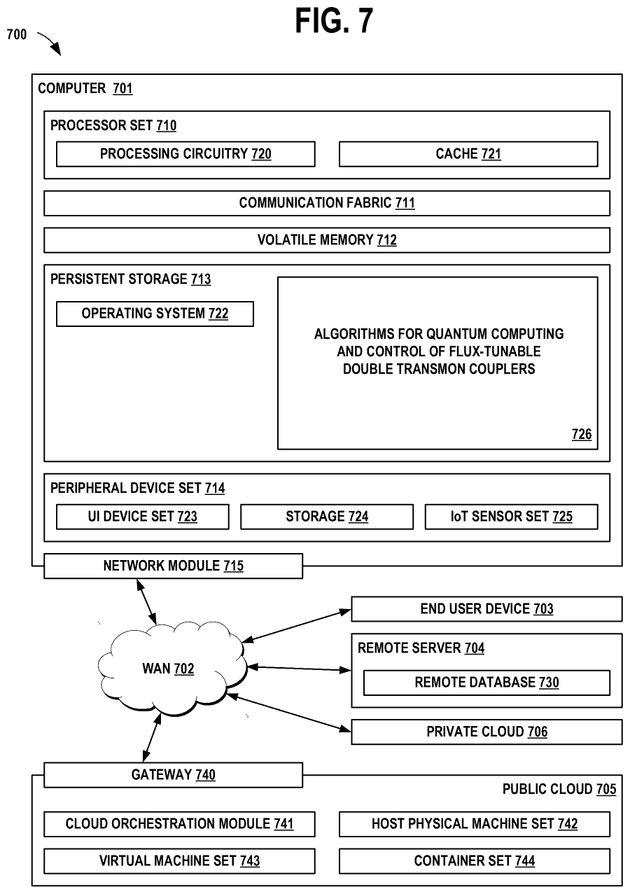

In some exemplary embodiments, the quantum computing platform 610 of the quantum computing system 600 may be implemented using any suitable computing system architecture (e.g., as shown in FIG. 7) which is configured to implement methods to support quantum computing operations by executing computer readable program instructions that are embodied on a computer program product which includes a computer readable storage medium (or media) having such computer readable program instructions thereon for causing a processor to perform control methods as discussed herein.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random-access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

FIG. 7 schematically illustrates an exemplary architecture of a computing environment 700 for hosting a quantum computing platform and performing quantum information processing, according to an exemplary embodiment of the disclosure. The computing environment 700 of FIG. 7 contains an example of an environment for the execution of at least some of the computer code (block 726) involved in executing, e.g., quantum computing algorithms, and control algorithms for controlling the activation and deactivation of flux-tunable double transmon couplers, as discussed herein. In addition to block 726, computing environment 700 includes, for example, computer 701, wide area network (WAN) 702, end user device (EUD) 703, remote server 704, public cloud 705, and private cloud 706. In this embodiment, computer 701 includes processor set 710 (including processing circuitry 720 and cache 721), communication fabric 711, volatile memory 712, persistent storage 713 (including operating system 722 and block 726, as identified above), peripheral device set 714 (including user interface (UI), device set 723, storage 724, and Internet of Things (IoT) sensor set 725), and network module 715. Remote server 704 includes remote database 730. Public cloud 705 includes gateway 740, cloud orchestration module 741, host physical machine set 742, virtual machine set 743, and container set 744.

Computer 701 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 730. As is well understood in the art of computer technology, and depending upon the technology, performance of a computer-implemented method may be distributed among multiple computers and/or between multiple locations. On the other hand, in this presentation of computing environment 700, detailed discussion is focused on a single computer, specifically computer 701, to keep the presentation as simple as possible. Computer 701 may be located in a cloud, even though it is not shown in a cloud in FIG. 7. On the other hand, computer 701 is not required to be in a cloud except to any extent as may be affirmatively indicated.

Processor set 710 includes one, or more, computer processors of any type now known or to be developed in the future. Processing circuitry 720 may be distributed over multiple packages, for example, multiple, coordinated integrated circuit chips. Processing circuitry 720 may implement multiple processor threads and/or multiple processor cores. Cache 721 is memory that is located in the processor chip package(s) and is typically used for data or code that should be available for rapid access by the threads or cores running on processor set 710. Cache memories are typically organized into multiple levels depending upon relative proximity to the processing circuitry. Alternatively, some, or all, of the cache for the processor set may be located “off chip.” In some computing environments, processor set 710 may be designed for working with qubits and performing quantum computing.

Computer readable program instructions are typically loaded onto computer 701 to cause a series of operational steps to be performed by processor set 710 of computer 701 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 721 and the other storage media discussed below. The program instructions, and associated data, are accessed by processor set 710 to control and direct performance of the inventive methods. In computing environment 700, at least some of the instructions for performing the inventive methods may be stored in block 726 in persistent storage 713.

Communication fabric 711 is the signal conduction path that allow the various components of computer 701 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 712 is any type of volatile memory now known or to be developed in the future. Examples include dynamic type random access memory (RAM) or static type RAM. Typically, the volatile memory is characterized by random access, but this is not required unless affirmatively indicated. In computer 701, the volatile memory 712 is located in a single package and is internal to computer 701, but, alternatively or additionally, the volatile memory may be distributed over multiple packages and/or located externally with respect to computer 701.

Persistent storage 713 is any form of non-volatile storage for computers that is now known or to be developed in the future. The non-volatility of this storage means that the stored data is maintained regardless of whether power is being supplied to computer 701 and/or directly to persistent storage 713. Persistent storage 713 may be a read only memory (ROM), but typically at least a portion of the persistent storage allows writing of data, deletion of data and re-writing of data. Some familiar forms of persistent storage include magnetic disks and solid-state storage devices. Operating system 722 may take several forms, such as various known proprietary operating systems or open source Portable Operating System Interface type operating systems that employ a kernel. The code included in block 726 typically includes at least some of the computer code involved in performing the inventive methods.

Peripheral device set 714 includes the set of peripheral devices of computer 701. Data communication connections between the peripheral devices and the other components of computer 701 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 723 may include components such as a display screen, speaker, microphone, wearable devices (such as goggles and smart watches), keyboard, mouse, printer, touchpad, game controllers, and haptic devices. Storage 724 is external storage, such as an external hard drive, or insertable storage, such as an SD card. Storage 724 may be persistent and/or volatile. In some embodiments, storage 724 may take the form of a quantum computing storage device for storing data in the form of qubits. In embodiments where computer 701 is required to have a large amount of storage (for example, where computer 701 locally stores and manages a large database) then this storage may be provided by peripheral storage devices designed for storing very large amounts of data, such as a storage area network (SAN) that is shared by multiple, geographically distributed computers. IoT sensor set 725 is made up of sensors that can be used in Internet of Things applications. For example, one sensor may be a thermometer and another sensor may be a motion detector.

Network module 715 is the collection of computer software, hardware, and firmware that allows computer 701 to communicate with other computers through WAN 702. Network module 715 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 715 are performed on the same physical hardware device. In other embodiments (for example, embodiments that utilize software-defined networking (SDN)), the control functions and the forwarding functions of network module 715 are performed on physically separate devices, such that the control functions manage several different network hardware devices. Computer readable program instructions for performing the inventive methods can typically be downloaded to computer 701 from an external computer or external storage device through a network adapter card or network interface included in network module 715.

WAN 702 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 703 is any computer system that is used and controlled by an end user (for example, a customer of an enterprise that operates computer 701), and may take any of the forms discussed above in connection with computer 701. EUD 703 typically receives helpful and useful data from the operations of computer 701. For example, in a hypothetical case where computer 701 is designed to provide a recommendation to an end user, this recommendation would typically be communicated from network module 715 of computer 701 through WAN 702 to EUD 703. In this way, EUD 703 can display, or otherwise present, the recommendation to an end user. In some embodiments, EUD 703 may be a client device, such as thin client, heavy client, mainframe computer, desktop computer and so on.

Remote server 704 is any computer system that serves at least some data and/or functionality to computer 701. Remote server 704 may be controlled and used by the same entity that operates computer 701. Remote server 704 represents the machine(s) that collect and store helpful and useful data for use by other computers, such as computer 701. For example, in a hypothetical case where computer 701 is designed and programmed to provide a recommendation based on historical data, then this historical data may be provided to computer 701 from remote database 730 of remote server 704.

Public cloud 705 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 705 is performed by the computer hardware and/or software of cloud orchestration module 741. The computing resources provided by public cloud 705 are typically implemented by virtual computing environments that run on various computers making up the computers of host physical machine set 742, which is the universe of physical computers in and/or available to public cloud 705. The virtual computing environments (VCEs) typically take the form of virtual machines from virtual machine set 743 and/or containers from container set 744. It is understood that these VCEs may be stored as images and may be transferred among and between the various physical machine hosts, either as images or after instantiation of the VCE. Cloud orchestration module 741 manages the transfer and storage of images, deploys new instantiations of VCEs and manages active instantiations of VCE deployments. Gateway 740 is the collection of computer software, hardware, and firmware that allows public cloud 705 to communicate through WAN 702.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 706 is similar to public cloud 705, except that the computing resources are only available for use by a single enterprise. While private cloud 706 is depicted as being in communication with WAN 702, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 705 and private cloud 706 are both part of a larger hybrid cloud.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, and to enable others of ordinary skill in the art to understand the embodiments disclosed herein.

What is claimed is:

1. A device, comprising:
a superconducting integrated circuit comprising a tunable coupler, the tunable coupler comprising:
a first node coupled to a first quantum bit, and a second node coupled to a second quantum bit;
a first transmon comprising a first Josephson junction;
a second transmon comprising a second Josephson junction; and
a flux-tunable inductive coupler which comprises a superconducting loop that couples the first transmon and the second transmon, the superconducting loop comprising a third Josephson junction;
wherein the first Josephson junction, the second Josephson junction, and the third Josephson junction are coupled in series between the first node and the second node of the tunable coupler.

2. The device of claim 1, wherein the flux-tunable inductive coupler comprises a radio frequency superconducting quantum interference device.

3. The device of claim 1, wherein:
the superconducting loop further comprises a fourth Josephson junction and a fifth Josephson junction;
the first transmon comprises a first capacitor which is coupled in parallel with the first Josephson junction and the fourth Josephson junction; and
the second transmon comprises a second capacitor which is coupled in parallel with the second Josephson junction and the fifth Josephson junction.

4. The device of claim 1, wherein:
the superconducting loop further comprises a first superconducting inductor and a second superconducting inductor;
the first transmon comprises a first capacitor which is coupled in parallel with the first Josephson junction and the first superconducting inductor; and
the second transmon comprises a second capacitor which is coupled in parallel with the second Josephson junction and the second superconducting inductor.

5. The device of claim 1, wherein:
the first transmon comprises a first capacitor having a first capacitor pad;
the second transmon comprises a second capacitor having a second capacitor pad; and
the first capacitor pad, the first Josephson junction, the second Josephson junction, the third Josephson junction, and the second capacitor pad are coupled in series between the first node and the second node of the tunable coupler.

6. The device of claim 1, further comprising:
a control line that is configured to generate a magnetic flux bias which threads through the superconducting loop of the flux-tunable inductive coupler to place the tunable coupler in one of: a first state to enable longitudinal coupling between the first quantum bit and the second quantum bit; and a second state to suppress longitudinal coupling between the first quantum bit and the second quantum bit;
wherein a tuning range of a magnitude of the magnetic flux bias between the first state and the second state is greater than about 0.3 magnetic flux quantum.

7. The device of claim 1, wherein:
the first quantum bit comprises a first transmon quantum bit that is capacitively coupled to the first node of the tunable coupler; and
the second quantum bit comprises a second transmon quantum bit that is capacitively coupled to the second node of the tunable coupler.

8. The device of claim 1, wherein the device comprises a quantum processor chip.

9. A device, comprising:
a superconducting integrated circuit comprising a tunable coupler which is configured to modulate interactions between a first quantum bit and a second quantum bit;
wherein the tunable coupler comprises:
a first transmon comprising a first Josephson junction, a second Josephson junction, and a first capacitor having a first capacitor pad;
a second transmon comprising a third Josephson junction, a fourth Josephson junction, and a second capacitor having a second capacitor pad; and
a flux-tunable inductive coupler which comprises a superconducting loop that couples the first transmon and the second transmon, the superconducting loop comprising a fifth Josephson junction, the second Josephson junction, and the fourth Josephson junction;
wherein the first Josephson junction, the second Josephson junction, and the fifth Josephson junction are coupled in series between the first capacitor pad and the second capacitor pad.

10. The device of claim 9, wherein the flux-tunable inductive coupler comprises a radio frequency superconducting quantum interference device.

11. The device of claim 9, wherein:
the first capacitor pad and the second capacitor pad are coupled to a ground plane;
the first Josephson junction and the second Josephson junction are serially connected to and between the first capacitor pad the ground plane; and
the third Josephson junction and the fourth Josephson junction are serially connected to and between the second capacitor pad the ground plane.

12. The device of claim 9, further comprising:
a control line that is configured to generate a magnetic flux bias which threads through the superconducting loop of the flux-tunable inductive coupler to place the tunable coupler in one of: a first state to enable longitudinal coupling between the first quantum bit and the second quantum bit; and a second state to suppress longitudinal coupling between the first quantum bit and the second quantum bit;
wherein a tuning range of a magnitude of the magnetic flux bias between the first state and the second state is greater than about 0.3 magnetic flux quantum.

13. The device of claim 9, wherein:
the first quantum bit comprises a first transmon quantum bit that is capacitively coupled to the first capacitor pad of the first transmon of the tunable coupler; and
the second quantum bit comprises a second transmon quantum bit that is capacitively coupled to the second capacitor pad of the second transmon of the tunable coupler.

14. A system, comprising:
a quantum processor comprising a first quantum bit, a second quantum bit, and a tunable coupler coupled to the first quantum bit and the second quantum bit; and
a control system to control operation of the quantum processor;
wherein the tunable coupler comprises:
a first node coupled to a first quantum bit, and a second node coupled to a second quantum bit;
a first transmon comprising a first Josephson junction;
a second transmon comprising a second Josephson junction; and
a flux-tunable inductive coupler which comprises a superconducting loop that couples the first transmon and the second transmon, the superconducting loop comprising a third Josephson junction;
wherein the first Josephson junction, the second Josephson junction, and the third Josephson junction are coupled in series between the first node and the second node of the tunable coupler; and
wherein the control system is configured to generate a control signal to place the tunable coupler in one of: a first state to enable longitudinal coupling between the first quantum bit and the second quantum bit; and a second state to suppress longitudinal coupling between the first quantum bit and the second quantum bit.

15. The system of claim 14, wherein the flux-tunable inductive coupler comprises a radio frequency superconducting quantum interference device.

16. The system of claim 14, wherein:
the superconducting loop further comprises a fourth Josephson junction and a fifth Josephson junction;
the first transmon comprises a first capacitor which is coupled in parallel with the first Josephson junction and the fourth Josephson junction; and
the second transmon comprises a second capacitor which is coupled in parallel with the second Josephson junction and the fifth Josephson junction.

17. The system of claim 14, wherein:
the superconducting loop further comprises a first superconducting inductor and a second superconducting inductor;
the first transmon comprises a first capacitor which is coupled in parallel with the first Josephson junction and the first superconducting inductor; and
the second transmon comprises a second capacitor which is coupled in parallel with the second Josephson junction and the second superconducting inductor.

18. The system of claim 14, wherein:
the first transmon comprises a first capacitor having a first capacitor pad;
the second transmon comprises a second capacitor having a second capacitor pad; and
the first capacitor pad, the first Josephson junction, the second Josephson junction, the third Josephson junction, and the second capacitor pad are coupled in series between the first node and the second node of the tunable coupler.

19. The system of claim 14, wherein:
the control signal is configured to generate a magnetic flux bias which threads through the superconducting loop of the flux-tunable inductive coupler to place the tunable coupler in one of the first state and the second state; and
a tuning range of a magnitude of the magnetic flux bias between the first state and the second state is greater than about 0.3 magnetic flux quantum.

20. The system of claim 14, wherein:
the first quantum bit comprises a first transmon quantum bit that is capacitively coupled to the first node of the tunable coupler; and
the second quantum bit comprises a second transmon quantum bit that is capacitively coupled to the second node of the tunable coupler.
